(19) United States
(12) Patent Application Publication
(10) Pub. No.: US 2026/0188419 A1
(43) Pub. Date: Jul. 2, 2026

(54) STORAGE DEVICE INCLUDING ERROR DETECTING CIRCUIT FOR DATA MIGRATION

(71) Applicant: Samsung Electronics Co., Ltd., Suwon-si (KR)

(72) Inventors: Jungho PARK, Suwon-si (KR); Junyeong Seok, Suwon-si (KR)

(73) Assignee: Samsung Electronics Co., Ltd., Suwon-si (KR)

(21) Appl. No.: 19/374,121

(22) Filed: Oct. 30, 2025

(30) Foreign Application Priority Data
Dec. 30, 2024 (KR) 10-2024-0199842

(51) Int. Cl. G11C 29/52; G11C 16/10; G11C 16/26

(52) U.S. Cl. CPC G11C 29/52; G11C 16/102; G11C 16/26

(57) ABSTRACT

A storage device includes a memory device that includes a plurality of memory cells, and a memory controller that controls the memory device. The memory device includes a memory cell array that includes the plurality of memory cells, a control logic circuit that writes data to the memory cell array or reads data from the memory cell array in response to a command received from the memory controller, and a page buffer that stores sensing data sensed from the plurality of memory cells. The control logic circuit includes an error detecting circuit that detects an error of first data stored in first memory cells of the memory cell array, and the control logic circuit writes the first data to second memory cells of the memory cell array, based on an error comparison result obtained by comparing the error of the first data with a preset value.

### CROSS-REFERENCE TO RELATED APPLICATION

This application claims priority under 35 U.S.C. § 119 to Korean Patent Application No. 10-2024-0199842 filed on December 30, 2024, in the Korean Intellectual Property Office, the disclosure of which is incorporated by reference herein in its entirety.

### BACKGROUND

Embodiments of the disclosure relate to a storage device and a method of operating the storage device, and more particularly, relate to a storage device including a memory device performing data migration without the output of data and a method of operating the storage device.

Data are increasing with the development of artificial intelligence (AI) technologies. This may increase the demand for large storage capacity in data centers. The use of a storage device based on semiconductor technology is increasing in the data centers and cloud computing environments.

As the use of the storage device increases, a technology for improving the performance of the storage device is being researched and developed. To migrate data in a memory device, a conventional storage device should necessarily output data to be migrated in the memory device to a memory controller. Also, error-checked data should be again input to the memory device.

### SUMMARY

Embodiments of the disclosure is directed to improve the performance of a storage device.

Embodiments of the disclosure provide a storage device performing data migration in a memory device without outputting the data from the memory device and inputting the data to the memory device, and an operating method of the storage device.

According to an embodiment, a storage device may include a memory device that includes a plurality of memory cells, and a memory controller that controls the memory device. The memory device may include a memory cell array that includes the plurality of memory cells, a control logic circuit that writes data to the memory cell array or reads data from the memory cell array in response to a command received from the memory controller, and a page buffer that stores sensing data sensed from the plurality of memory cells. The control logic circuit may include an error detecting circuit that detects an error of first data stored in first memory cells of the memory cell array, and the control logic circuit may be configured to write the first data to second memory cells of the memory cell array, based on an error comparison result obtained by comparing the error of the first data with a set value.

According to an embodiment, a storage device may include a memory device that includes a plurality of memory cells, and a memory controller that controls the memory device. The memory device may include a memory cell array that includes the plurality of memory cells, a control logic circuit that writes data to or from the memory cell array or reads data from the memory cell array in response to a command received from the memory controller, and a page buffer that stores sensing data sensed from the plurality of memory cells. The control logic circuit may include an error detecting circuit that compares a change in an on-cell count of first memory cells among the plurality of memory cells with a set value to generate a comparison result by changing voltage levels of a plurality of sensing voltages, and the control logic circuit may be configured to write first data of the first memory cells in second memory cells among the plurality of memory cells, based on the comparison result.

According to an embodiment, an operating method of a storage device may include sending, by a controller controlling a memory device, a first command to the nonvolatile memory device, detecting an error of first data stored in first memory cells of a memory cell array in response to the first command, comparing the error of the first data with a set value to generate an error comparison result, and writing the first data to second memory cells of the memory cell array based on the error comparison result.

### BRIEF DESCRIPTION OF DRAWINGS

The above and other objects and features of the disclosure will become apparent by describing in detail embodiments thereof with reference to the accompanying drawings.

FIG. 1 is a block diagram illustrating a storage device according to an embodiment of the disclosure.

FIG. 2 is a block diagram illustrating an example of an operation of the storage device of FIG. 1.

FIG. 3 is a diagram illustrating an example of an error detecting operation of a memory device of FIG. 1.

FIG. 4 is a block diagram illustrating an example of a configuration of a memory controller of FIG. 1.

FIG. 5 is a flowchart illustrating an operation of a storage device according to an embodiment of the disclosure.

FIG. 6 is a diagram illustrating command transmission of a storage device according to the embodiment of FIG. 5.

FIG. 7 is a diagram illustrating a configuration of a command according to the embodiment of FIG. 6.

FIG. 8 is a flowchart illustrating an operation of a storage device according to an embodiment of the disclosure.

FIG. 9 is a diagram illustrating command transmission of a storage device according to the embodiment of FIG. 8.

FIG. 10 is a diagram illustrating a configuration of a command according to the embodiment of FIG. 9.

FIG. 11 is a diagram illustrating a configuration of a nonvolatile memory device of a storage device according to an embodiment of the disclosure.

FIG. 12 is a diagram illustrating a memory block of a three-dimensional V-NAND structure applicable to a storage device according to an embodiment of the disclosure in detail.

FIG. 13 is a block diagram illustrating an example of a configuration of a memory device of FIG. 1.

FIG. 14 is a block diagram illustrating an example of a configuration of an error detecting circuit of FIG. 13.

FIGS. 15A, 15B, and 15C are diagrams illustrating an embodiment of an error detecting method of an error detecting circuit according to an embodiment of the disclosure.

FIG. 16 is a diagram illustrating an embodiment of an error detecting method of an error detecting circuit according to an embodiment of the disclosure.

### DETAILED DESCRIPTION

Below, embodiments of the disclosure will be described in detail and clearly to such an extent that an ordinary one in the art readily carries out the disclosure. Unless otherwise specified herein, a memory cell refers to a non-volatile memory cell and a memory device refers to a memory device including the non-volatile memory cell.

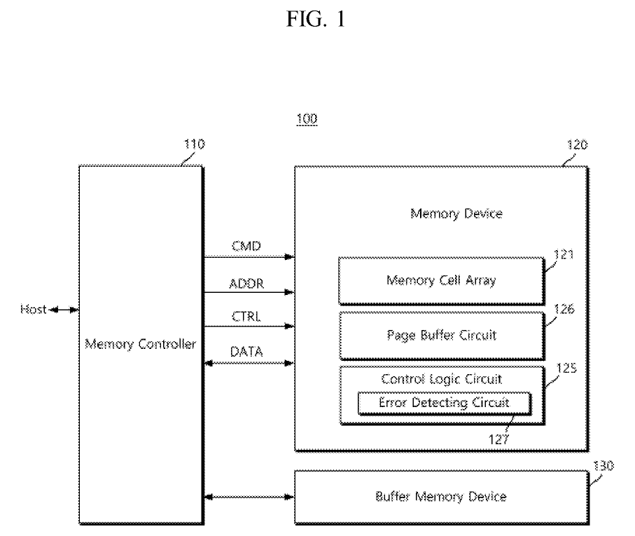

FIG. 1 is a block diagram illustrating a storage device according to an embodiment of the disclosure.

Referring to FIG. 1, a storage device 100 may include a memory controller 110, a memory device 120, and a buffer memory device 130.

The storage device 100 according to an embodiment of the disclosure may perform data migration through an internal operation of the memory device 120, e.g., without sending the data to the memory controller 110. The memory device 120 may detect an error of data to be migrated, and based on the detected error, the memory device 120 may perform data migration through an internal operation of the memory device 120.

The storage device 100 according to an embodiment of the disclosure will be described in detail with reference to FIG. 1.

The memory controller 110 may control the memory device 120 to perform an input/output request of a host. The memory controller 110 may be configured to control the memory device 120 under control of the host or according to a command from the host. The input/output request may include write, read, and/or erase operations on user data, which are requested by the host and performed by the storage device 100. For example, according to a request of the host, the memory controller 110 may write data to the memory device 120 or may read data stored in the memory device 120. To control the memory device 120, the memory controller 110 may provide the memory device 120 with a command CMD, an address ADDR, data DATA, and a control signal CTRL.

The memory device 120 may store data received from the memory controller 110 or may send the stored data to the memory controller 110. The memory device 120 may function as a storage medium of the storage device 100. For example, the memory device 120 may be formed as a NAND-type flash memory having a high-capacity storage capability. The memory device 120 may include a plurality of nonvolatile memory devices. For example, the memory device 120 may include a plurality of flash memory devices. The memory device 120 may include a flash memory device of a two-dimensional (2D) structure or a three-dimensional (3D) structure. The flash memory device may include different kinds of nonvolatile memories such as a NAND flash memory, a vertical NAND (V-NAND) flash memory, a NOR flash memory, a magnetic memory (MRAM), a phase-change memory (PRAM), a ferroelectric random access memory (FRAM), a spin transfer torque random access memory (STT-RAM), and/or a resistive RAM (RRAM).

For example, the plurality of flash memory devices may be connected to the memory controller 110 in units of channels. A plurality of flash memory devices, which communicate through a data bus, may be connected to one channel. The memory device 120 may communicate with the memory controller 110 in a channel/way interleaving manner.

The buffer memory device 130 may be used as a data buffer for exchanging data between the storage device 100 and the host. Write data provided from the host or data read from the memory device 120 may be temporarily stored in the buffer memory device 130. When data, which are requested by the host and are stored in the memory device 120, are cached in the buffer memory device 130, the buffer memory device 130 may support a cache function of providing the cached data directly to the host. The buffer memory device 130 may be implemented as a synchronous DRAM (SDRAM) such that the storage device 100 used as a high-capacity auxiliary storage device may provide sufficient buffering. However, it is understood that the buffer memory device 130 is not limited to the disclosure.

The memory device 120 may include a memory cell array 121, a control logic circuit 125, and a page buffer circuit 126.

The memory cell array 121 may include a plurality of memory blocks, and each of the plurality of memory blocks may include a plurality of memory cells.

The control logic circuit 125 may overall control various operations of the memory device 120. For example, in response to a command received from the memory controller 110, the control logic circuit 125 may write data to memory cells of the memory cell array 121 or may read data from the memory cells.

In the read operation of the memory device 120, the page buffer circuit 126 may read data stored in a memory cell by sensing a current or a voltage of a selected bit line. The page buffer circuit 126 may temporarily store the sensed data.

The control logic circuit 125 according to an embodiment of the disclosure may perform data migration in the memory device 120 in response to the command received from the memory controller 110. For example, the control logic circuit 125 may migrate first data stored in a first memory cell of the memory device 120 to a second memory cell of the memory device 120.

In an embodiment, the control logic circuit 125 may include an error detecting circuit 127 which detects an error of the first data.

Based on the error, which is detected by the error detecting circuit 127 from the first data, the control logic circuit 125 may migrate the first data from the first memory cell to the second memory cell without outputting the first data to the memory controller 110.

For example, when the number of errors detected by the error detecting circuit 127 is not greater than preset criteria, preset value(s), and/or set value(s), the control logic circuit 125 may migrate the first data from the first memory cell to the second memory cell without outputting the first data to the memory controller 110. The terms “preset value(s)” or “set value(s)” may include one or more criteria, thresholds, or reference levels for comparison. When the number of errors detected by the error detecting circuit 127 is greater than the preset criteria, for error correction, the control logic circuit 125 may output the first data to the memory controller 110. For example, for the migration of the first data, the control logic circuit 125 may again receive the first data whose error is corrected by the memory controller 110.

In the storage device 100 according to an embodiment of the disclosure, the memory device 120 may detect an error of data to be migrated. When the number of the detected errors is not greater than the preset criteria, the memory device 120 may internally perform data migration without outputting the data to the memory controller 110. Accordingly, the unnecessary data input/output load between the memory device 120 and the memory controller 110 may be reduced, thereby improving the performance of the storage device 100.

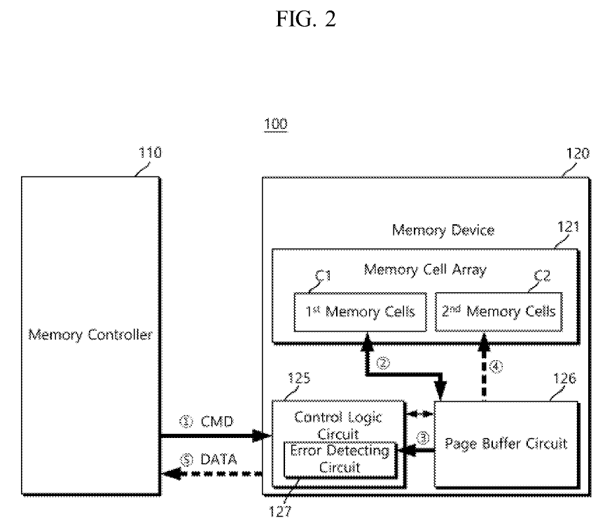

FIG. 2 is a block diagram illustrating an example of an operation of the storage device 100 of FIG. 1. For convenience of description, the buffer memory device 130 of FIG. 1 is omitted in FIG. 2.

Referring to FIG. 2, the memory device 120 may receive a first command from the memory controller 110. The first command which is a command indicating the migration of first data may be a read command or a migration command. When the first command is based on the read command, a reserved bit signal of the read command may include a bit signal indicating migration or a bit signal indicating error detection.

The control logic circuit 125 may direct or control the page buffer circuit 126 to sense the first data of a first memory cell C1 in response to the first command. In an embodiment, the page buffer circuit 126 may sense the first data multiple times based on a plurality of voltage signals. In an embodiment, pieces of data (hereinafter referred to as “sensing data of the first data”) obtained by sensing the first data multiple times may be provided to the error detecting circuit 127 of the control logic circuit 125. In an embodiment, an on-cell count associated with the sensing data of the first data may be provided to the error detecting circuit 127. For example, the page buffer circuit 126 may include an on-cell counting circuit.

The error detecting circuit 127 may detect an error of the first data based on the sensing data of the first data, which are obtained based on the plurality of voltage signals, or the on-cell count.

The error detecting circuit 127 may compare the error of the first data with the preset criteria and may output an error comparison result.

When the number of errors is in (or is not greater than) the preset criteria, the control logic circuit 125 may program the first data to a second memory cell C2, based on the error comparison result.

In an embodiment, when the number of errors is in the preset criteria, the control logic circuit 125 may send the error comparison result to the memory controller 110 by using a status register. The memory controller 110 may send a second command to the memory device 120 based on the error comparison result, and the control logic circuit 125 may program the first data to the second memory cell C2 in response to the second command.

In an embodiment, when the number of errors is in the preset criteria, the control logic circuit 125 may program the first data to the second memory cell C2 without receiving an additional command from the memory controller 110. After the programming of the first data to the second memory cell C2 is completed, the control logic circuit 125 may notify the memory controller 110 that the migration of the first data is completed, by using the status register.

When the number of errors exceeds the preset criteria, the control logic circuit 125 may send the first data to the memory controller 110, based on the error comparison result.

In an embodiment, when the number of errors exceeds (or is greater than) the preset criteria, the control logic circuit 125 may send the error comparison result to the memory controller 110 by using the status register. The memory controller 110 may direct or control the memory device 120 to output the first data based on the error comparison result, and the control logic circuit 125 may send the first data to the memory controller 110. After the memory controller 110 performs error correction on the first data, the memory controller 110 may send the first data thus error-corrected to the memory device 120. The control logic circuit 125 may program the error-corrected first data in the second memory cell C2.

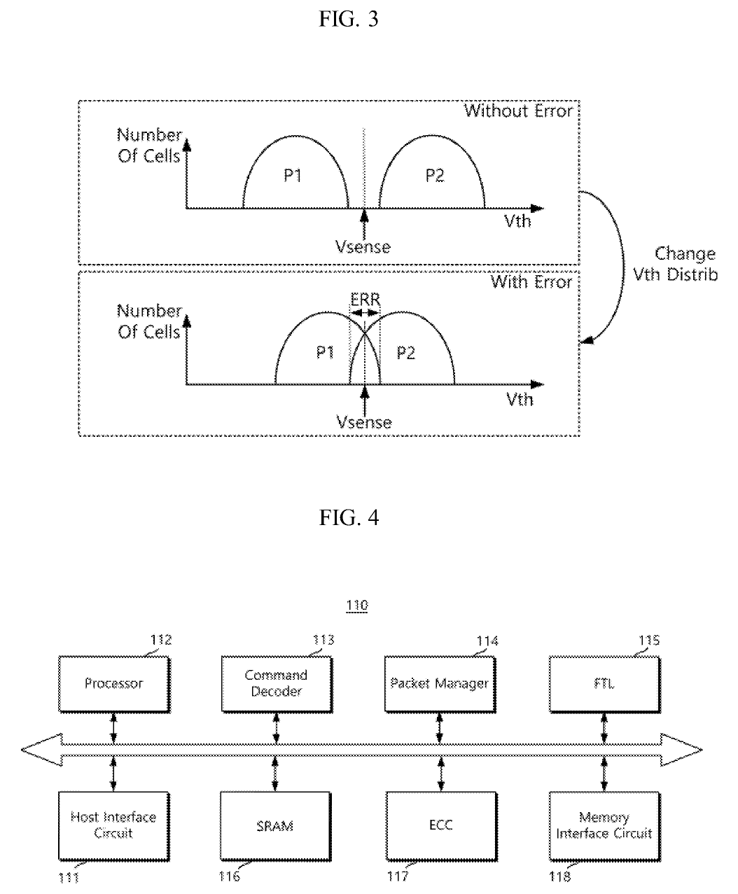

FIG. 3 is a diagram illustrating an example of an error detecting operation of the memory device 120 of FIG. 1. FIG. 3 shows an example of an operation in which the memory device 120 detects an error of first data stored in a first memory cell, which is implemented as a single level cell (SLC). However, the disclosure is not limited to a specific memory cell such as a multi-level cell (MLC), a triple level cell (TLC), a quadruple level cell (QLC), etc.

FIG. 3 shows distributions of threshold voltages Vth when the first data do not include an error (“without error”) and when the first data include an error (“with error”).

When no error is present in data stored in memory cells being single level cells, a distribution of threshold voltages having a first program state P1 may be spaced apart from a distribution of threshold voltages having a second program state P2. For example, the threshold voltage distribution based on the first program state P1 and the threshold voltage distribution based on the second program state P2 may be separated from each other by a valley.

When an error is present in pieces of data stored in memory cells being single level cells, a distribution of threshold voltages having the first program state P1 may partially overlap a distribution of threshold voltages having the second program state P2. For example, due to the iteration of the read/write operation or a change in a temperature, the threshold voltage distributions of the first program state P1 and the second program state P2 may move or shift. As the threshold voltage distributions of memory cells are changed or shifted, a read voltage level for reading data from a memory cell may also change.

For example, the threshold voltage distribution based on the first program state P1 and the threshold voltage distribution based on the second program state P2 may be incapable of being separated from each other by a valley. Accordingly, when a threshold voltage of a memory cell is in an error range ERR, data sensed from the memory cell based on a sensing voltage Vsense may include an error.

The error detecting circuit 127 of FIG. 1 may detect a change in the first data sensed from first memory cells while changing the sensing voltage Vsense and may determine whether the first data include an error based on the detected change in the first data.

The error detecting circuit 127 may compare the change in the first data with the preset criteria to determine whether to perform migration of the first data or whether the output of the first data is required for error correction by the memory controller 110.

For example, the error detecting circuit 127 of FIG. 1 may compare a change in the number of on-cell data with the preset criteria based on a plurality of sensing voltage signals. In another example, the error detecting circuit 127 may compare hard decision data with soft decision data to generate a difference between the hard decision data and the soft decision data, and may compare the difference between the hard decision data and the soft decision data with the preset criteria. For example, the error detecting circuit 127 may determine whether data to be migrated include an error, by using various lightweight error detecting methods.

FIG. 4 is a block diagram illustrating an example of a configuration of the memory controller 110 of FIG. 1.

The memory controller 110 may include a host interface circuit 111, a processor 112, a command decoder 113, a packet manager 114, a flash translation layer (FTL) 115, an SRAM 116, an error correction code (ECC) module 117, and a memory interface circuit 118.

The memory controller 110 may communicate with the host through the host interface circuit 111. The host interface circuit 111 may be implemented as various interface manners (or interface protocols) such as advanced technology attachment (ATA), serial ATA (SATA), external SATA (e-SATA), small computer small interface (SCSI), serial attached SCSI (SAS), peripheral component interconnection (PCI), PCI express (PCIe), IEEE 1394, universal serial bus (USB), non-volatile memory express (NVMe), and compute express link (CXL).

The processor 112 may be implemented with a circuit, logic, a code, or a combination thereof. The processor 112 may control all operations of the storage device 100 including the memory controller 110. When the storage device 100 is driven (or powered on), the processor 112 may load the firmware stored in a read only memory (ROM) to a working memory and may perform all operations of the memory controller 110. The processor 112 may load the flash translation layer (FTL) 115 to the working memory; based on an address translation result of the flash translation layer (FTL) 115, the processor 112 may program data to the memory device 120 and/or may read data from the memory device 120.

The command decoder 113 may decode a command parsed from a packet received from the host, based on the protocol agreed upon between the host and the interface. The packet manager 114 may parse the command from the packet received from the host, based on the protocol agreed upon between the host and the interface. For example, the command decoder 113 may decode an opcode of a command which is based on a specific protocol and may identify a program command, an erase command, a read command, and/or a secure erase command. The processor 112 may perform the request of the host according to the decoded command. In an embodiment, the command decoder 113 may be implemented as an independent circuit and/or part of firmware.

The flash translation layer (FTL) 115 may perform various functions such as an address mapping operation, a wear-leveling operation, and a garbage collection operation.

The address mapping operation refers to an operation of translating a logical address received from the host into a physical address, which is actually used to program data to the memory device 120. For example, a logical block address (LBA) of user data which are requested by the host to be programmed may be translated into a physical address of the memory device 120 of FIG. 1 by the flash translation layer (FTL) 115. In an embodiment, the physical address may be a physical page number (PPN). In an embodiment, an address mapping table, which the flash translation layer (FTL) 115 manages, may store a mapping relationship between a logical page number (LPN) and a physical page number. In an embodiment, each of logical page numbers (LPNs) may correspond to a plurality of logical block addresses (LBAs).

In an embodiment, the flash translation layer (FTL) 115 may include information about a kind of the memory cells of the memory cell array 121 of FIG. 1. For example, the flash translation layer (FTL) 115 may include information indicating that memory cells in a first zone are implemented with single level cells (SLCs), while memory cells in a second zone are implemented with any other cells such as multi-level cells (MLCs) or triple level cells (TLCs) other than the single level cells (SLCs).

Wear-leveling, which is a technology for enabling uniform use of blocks of the memory device 120 of FIG. 1 to prevent excessive degradation of a specific block, may be implemented, for example, through a firmware technology for balancing erase counts of physical blocks. The garbage collection refers to a technology for securing an available capacity of the memory device 120 of FIG. 1 through a way to copy valid data of a block to a new block and then erasing the previous block.

The SRAM 116 may store temporary data, temporary variables, etc. for performing the operation of the processor 112.

The error correction code (ECC) module 117 may add parity information by performing ECC encoding on data to be programmed in the memory device 120 of FIG. 1. For example, the ECC module 117 may detect an error bit in the data read from the memory device 120. For example, the memory controller 110 may detect an error bit by performing ECC decoding on the read data. The ECC module 117 may correct an error bit detected in an error correction range. The ECC module 117 may be implemented as an independent circuit and/or part of firmware.

The memory controller 110 according to an embodiment of the disclosure may request the migration of the first data from the memory device 120 of FIG. 1. For example, the memory controller 110 may request the memory device 120 to store (or migrate) the first data of first memory cells in second memory cells.

To direct or perform the migration of the first data, the memory controller 110 may send a read command including a bit signal indicating migration, or a migration command to the memory device 120.

After the memory controller 110 directs the memory device 120 to perform migration, the memory controller 110 may check a status register of the memory device 120.

For example, the memory controller 110 may send a status query command to the memory device 120. For example, the memory controller 110 may send a read status command to the memory device 120.

For example, the memory controller 110 may monitor a ready/busy signal (R/B) of the memory device 120. In an embodiment, after the ready/busy signal (R/B) transitions to a ready state, the memory controller 110 may send the status query command to the memory device 120.

In an embodiment, when the memory controller 110 receives data, which include error and are requested to be migrated from the memory device 120, the memory controller 110 may direct or control the memory device 120 to output the data. The ECC module 117 of the memory controller 110 may correct the error of the data to be migrated and may again send the error-corrected data back to the memory device 120.

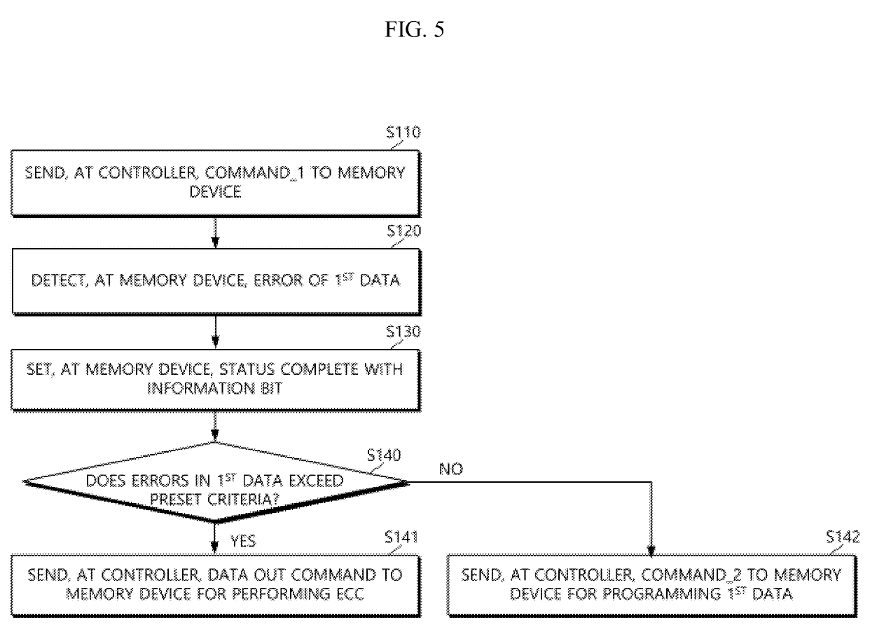

FIG. 5 is a flowchart illustrating operations of a storage device according to an embodiment of the disclosure. The operations of FIG. 5 may be performed by the storage device 100 of FIG. 1. An operation of the storage device 100 will be described with reference to FIGS. 1 and 5.

In operation S110, the memory controller 110 may send a first command to the memory device 120. The first command may be a read command including a bit signal indicating migration. For example, the first command may be a read command in which the bit signal indicating migration is included as a reserved bit signal of a conventional read command for reading first data stored in first memory cells.

In operation S120, the memory device 120 may perform error detection on the first data. For example, the memory device 120 may detect an error of the first data by using a plurality of voltage signals having different sensing levels.

The memory device 120 may compare the detected error of the first data with the preset criteria. In an embodiment, even when the same number of error bits are detected in the first data by using the plurality of voltage signals having different sensing levels, the memory device 120 may differently determine an error detection result as success or failure according to the preset criteria. For example, when a first number of error bits detected in the first data by using a first voltage signal having a first sensing level, and a second number of error bits detected in the first data by using a second voltage signal having a second sensing level are the same as each other, the memory device 120 may compare the first number to the preset criteria. And the memory device 120 may determine the error detection result as success or failure according to the comparison result.

After the error detecting operation is completed in operation S120, the memory device 120 may change the status register based on the error detection result.

After the memory controller 110 sends the first command to the memory device 120, the memory controller 110 may send a status query command to the memory device 120. In an embodiment, after the error detecting operation on the first data is completed, the memory device 120 may change or update the status register.

When the error of the migration-requested data exceeds the preset criteria, the memory device 120 may set an error information bit of the status register to indicate failure. When the error of the migration-requested data is in the preset criteria, the memory device 120 may set the error information bit of the status register to indicate success. For example, the status register may include a plurality of bit signals, and the memory device 120 may set a bit signal corresponding to the error information bit from among the bit signals of the status register to indicate either failure or success.

In operation S140, the memory controller 110 may check the status register.

When a result of checking the status register indicates that the error of the migration-requested data exceeds the preset criteria, in operation S141, the memory controller 110 may send a command directing (or instructing) the output of the first data to the memory device 120.

When the result of checking the status register indicates that the error of the migration-requested data is in the preset criteria, in operation S142, the memory controller 110 may send the second command instructing programming of the first data to the second memory cells to the memory device 120.

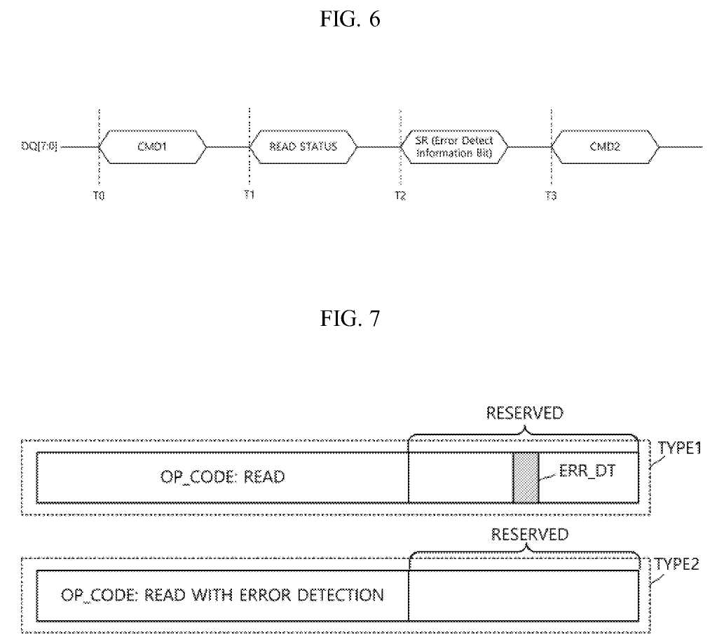

FIG. 6 is a diagram illustrating commands for an operation of the storage device 100 according to the embodiment of FIG. 5. The commands are illustrated in FIG. 6 under the condition that commands and data are exchanged through the same channel. However, in other examples, commands and addresses may be exchanged through a channel different from that of data according to embodiments.

Referring to FIG. 6, at a time point T0, the memory controller 110 may send a first command CMD1 to the memory device 120. In operation S110 of FIG. 5, the first command CMD1 may be sent to the memory device 120.

In an embodiment, referring to FIG. 7, the first command CMD1 may be a read command TYPE1 in which some of reserved bit signals are set to a bit signal ERR_DT to direct or instruct error detection. For example, an operation code OP_CODE may be the same as an operation code of the conventional read command.

In an embodiment, referring to FIG. 7, the first command CMD1 may be a read command TYPE2 indicating sensing of the first data together with error detection. For example, the operation code OP_CODE may be different from the operation code of the conventional read command.

After the transmission of the first command CMD1 is completed, e.g., at a time point T1, the memory controller 110 may send the status query command to the memory device 120. For example, the status query command may be a read status command. At the time point T1, the memory device 120 may be performing the sensing operation and the error detecting operation on the first data.

After the sensing operation and the error detecting operation on the first data are completed, e.g., at a time point T2, the memory device 120 may change or update the status register.

The memory device 120 may change or update the status register based on a result of the error detecting operation. For example, the status register may include a plurality of bit signals, and the memory device 120 may set an error detection information bit among the bit signals of the status register to indicate either failure or success based on the result of the error detecting operation.

In an embodiment, the memory device 120 may set the ready/busy signal (R/B) to the ready state and may change or update the status register.

At a time point T3, the memory controller 110 may check the status register. The memory controller 110 may send a second command CMD2 to the memory device 120 based on the status register. For example, when the error detection information bit of the status register indicates “success”, the memory controller 110 may send a program command to the memory device 120; when the error detection information bit of the status register indicates “failure”, the memory controller 110 may send a data output command to the memory device 120. In an embodiment, the program command may be sent together with an address of a second memory cell to which the first data are to be migrated.

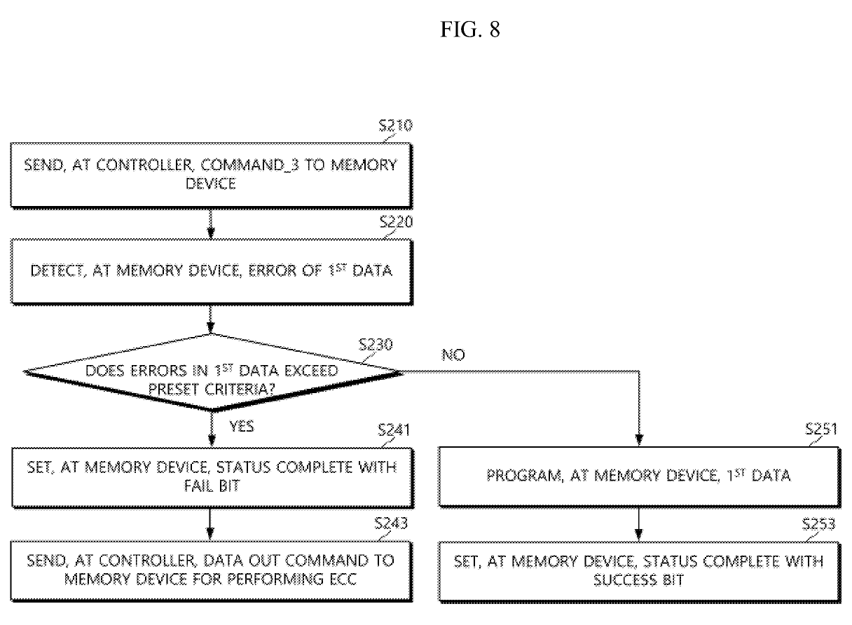

FIG. 8 is a flowchart illustrating operations of a storage device according to an embodiment of the disclosure. The operations of FIG. 8 may be performed by the storage device 100 of FIG. 1. An operation of the storage device 100 will be described with reference to FIGS. 1 and 8.

In operation S210, the memory controller 110 may send a third command to the memory device 120. The third command may be a migration command directing (or instructing) migration together with error detection. For example, the third command may be a command directing (or instructing) the programming of first data to second memory cells after an error of the first data stored in first memory cells is detected.

In operation S220, the memory device 120 may perform error detection on the first data. For example, the memory device 120 may detect an error of the first data by using a plurality of voltage signals having different sensing levels. Operation S220 may be the same as or similar to operation S120 of FIG. 5. The memory device 120 may compare the error, which is detected from the first data, with the preset criteria.

In operation S230, the memory device 120 may check the error, which is detected from the first data.

When the error, which is detected from the first data exceeds the preset criteria, in operation S241, the memory device 120 may set an error information bit of a status register to indicate failure.

In operation S243, in response to the error information bit of the status register set to indicate failure, the memory controller 110 may check the status register and may send a command requesting the output of the first data to the memory device 120. The ECC module 117 of the memory controller 110 may perform error correction on the first data.

When the error, which is detected from the first data is in the preset criteria, in operation S251, the memory device 120 may program the first data to the second memory cells.

When the first data are completely programmed in the second memory cells, in operation S253, the memory device 120 may set the error information bit of the status register to indicate success.

In an embodiment, unlike the embodiment of FIG. 5, in response to the migration command directing (or instructing) migration together with error detection, the memory controller 110 may change or update the status register immediately when an error of data to be migrated exceeds the preset criteria, and when an error of data to be migrated is in the preset criteria, may change or update the status register after the migration is completed.

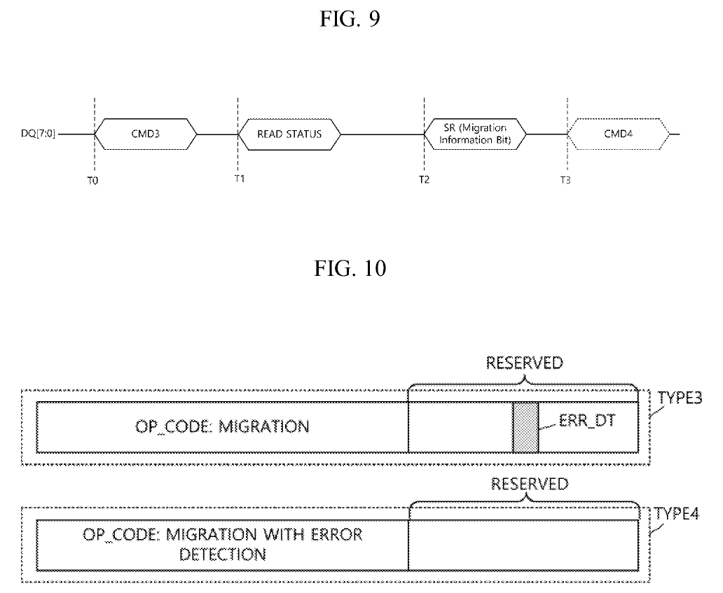

FIG. 9 is a diagram illustrating commands for an operation of the storage device 100 according to the embodiment of FIG. 8. The commands are illustrated in FIG. 9 under the condition that commands and data are exchanged through the same channel. However, commands and addresses may be exchanged through a channel different from that of data according to embodiments.

Referring to FIG. 9, at a time point T0, the memory controller 110 may send a third command CMD3 to the memory device 120. In operation S210 of FIG. 8, the third command CMD3 may be sent to the memory device 120.

In an embodiment, referring to FIG. 10, the third command CMD3 may be a migration command TYPE3 indicating migration of the first data. Some of reserved bit signals of the migration command TYPE3 may include a bit signal ERR_DT indicating error detection.

In an embodiment, referring to FIG. 10, the third command CMD3 may be a migration command TYPE4 indicating migration of the first data together with error detection. For example, the operation code OP_CODE of the migration command TYPE4 may be different from the operation code OP_CODE of the migration command TYPE3 directing (or instructing) migration of the first data without error detection.

In an embodiment, the third command CMD3 may be sent together with an address of second memory cells to which the first data are to be migrated.

After the transmission of the third command CMD3 is completed, e.g., at a time point T1, the memory controller 110 may send the status query command to the memory device 120. For example, the status query command may be a read status command. At the time point T1, the memory device 120 may be performing any one of a sensing operation on the first data, the error detecting operation, and a programming operation on the first data.

At a time point T2, the memory device 120 may change or update the status register.

In an embodiment, a time point at which the first data sensing operation and the error detecting operation are completed and it is determined that an error of the first data exceeds the preset criteria may be followed by the time point T2.

In an embodiment, a time point at which the first data sensing operation, the error detecting operation, and the operation of programming the first data to the second memory cells may be followed by the time point T2. For example, the error of the first data may be in the preset criteria.

The memory device 120 may set the migration information bit among the bit signals of the status register to indicate either failure or success, based on the result of the error detecting operation.

For example, when it is determined that the error of the first data exceeds the preset criteria, the memory device 120 may set the migration information bit to indicate failure. When the error of the first data is in the preset criteria, the memory device 120 may complete the programming of the first data and may then set the migration information bit to indicate success.

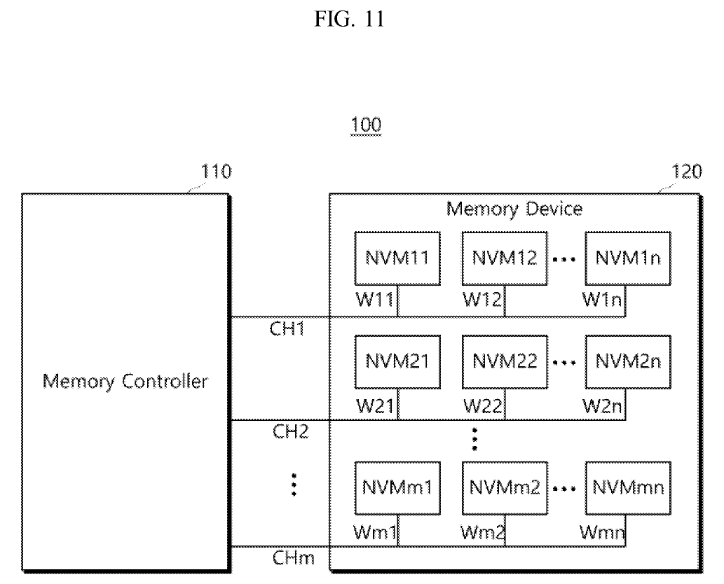

FIG. 11 is a diagram illustrating a configuration of a nonvolatile memory device of a storage device according to an embodiment of the disclosure. The storage device 100, the memory controller 110, and the memory device 120 of FIG. 11 may respectively correspond to the storage device 100, the memory controller 110, and the memory device 120 of FIG. 1.

The memory controller 110 may perform an input/output (I/O) on a plurality of memory devices NVM11 to NVMmn through a plurality of channels CH1 to CHm. The memory device 120 and the memory controller 110 may be connected through the plurality of channels CH1 to CHm. In an embodiment, the memory controller 110 may include a plurality of controller modules respectively corresponding to the plurality of channels CH1 to CHm.

The memory controller 110 may independently control memory devices (e.g., NVM11 to NVM1n) connected to one of the plurality of channels CH1 to CHm through ways.

The memory controller 110 may exchange signals with the memory device 120 through the plurality of channels CH1 to CHm.

The memory device 120 may include the plurality of nonvolatile memory devices NVM11 to NVMmn. Each of the nonvolatile memory devices NVM11 to NVMmn may be a nonvolatile memory package. In an embodiment, each of the nonvolatile memory devices NVM11 to NVMmn may include a plurality of dies, but the disclosure is not limited thereto.

In an embodiment, according to the data migration of the disclosure, a control logic circuit of a nonvolatile memory device may detect an error of first data of a first memory cell of the same nonvolatile memory device and may then program the first data to a second memory cell of the same nonvolatile memory device.

In an embodiment, according to the data migration of the disclosure, a control logic circuit of a first nonvolatile memory device may detect an error of first data of a first memory cell of the first nonvolatile memory device, and then, a control logic circuit of a second nonvolatile memory device may program the first data to a second memory cell of the second nonvolatile memory device.

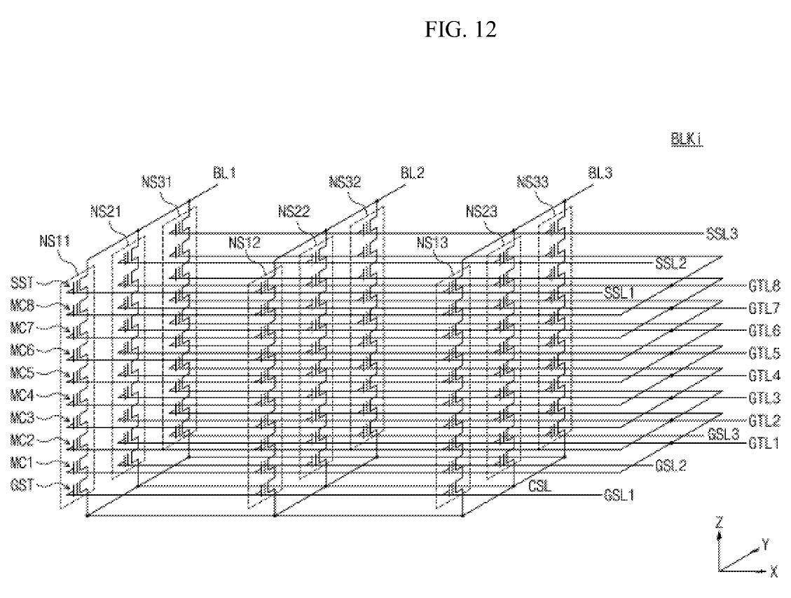

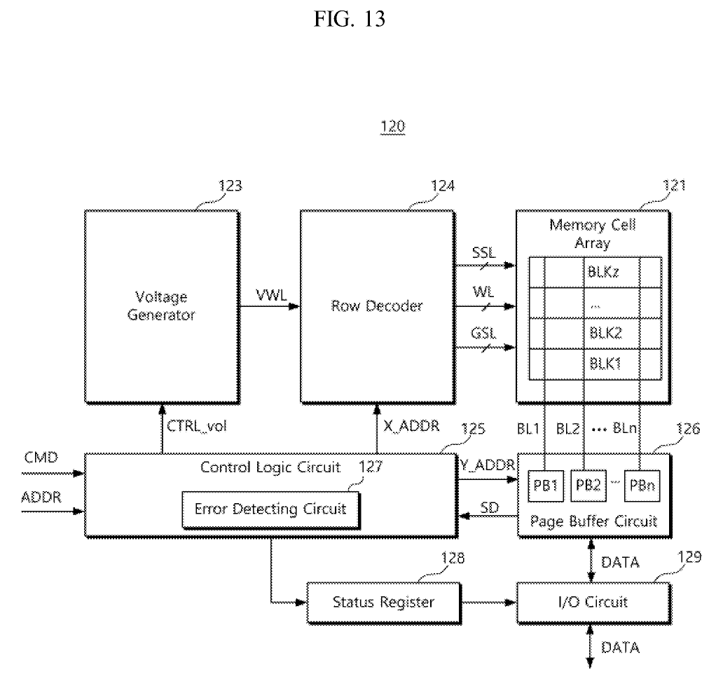

FIG. 12 is a diagram illustrating a configuration according to an embodiment of a memory block, according to an embodiment of the disclosure. A memory block BLKi of FIG. 12 may be one of the memory blocks BLK1 to BLKz included in the memory cell array 121 of the memory device 120 of FIG. 1.

When the memory device 120 of the storage device 100 of FIG. 1 is implemented with a flash memory of a three-dimensional (3D) V-NAND type, each of a plurality of memory blocks constituting the memory device 120 may be represented by an equivalent circuit illustrated in FIG. 12.

The memory block BLKi illustrated in FIG. 12 may represent a three-dimensional memory block formed on a substrate in a three-dimensional structure. For example, a plurality of memory NAND strings included in the memory block BLKi may be formed in a direction perpendicular to the substrate.

Referring to FIG. 12, the memory block BLKi may include a plurality of memory NAND strings NS11 to NS33 connected between bit lines BL1, BL2, and BL3 and a common source line CSL. Each of the plurality of memory NAND strings NS11 to NS33 may include a string selection transistor SST, a plurality of memory cells MC1, MC2, ..., and MC8, and a ground selection transistor GST. An embodiment in which each of the plurality of memory NAND strings NS11 to NS33 includes eight memory cells MC1, MC2, ..., and MC8 is illustrated in FIG. 12, but an embodiment of the disclosure is not limited thereto.

The string selection transistor SST may be connected to a corresponding one of string selection lines SSL1, SSL2, and SSL3. The plurality of memory cells MC1, MC2, ..., and MC8 may be respectively connected to gate lines GTL1, GTL2, ..., and GTL8. The gate lines GTL1, GTL2, ..., and GTL8 may correspond to word lines, and at least one of the gate lines GTL1, GTL2, ..., and GTL8 may correspond to a dummy word line. The ground selection transistor GST may be connected to a corresponding one of ground selection lines GSL1, GSL2, and GSL3. The string selection transistor SST may be connected to a corresponding bit line among the bit lines BL1, BL2, and BL3, and the ground selection transistor GST may be connected to the common source line CSL.

Word lines (e.g., WL1) at the same height may be connected in common, the ground selection lines GSL1, GSL2, and GSL3 may be separated from each other, and the string selection lines SSL1, SSL2, and SSL3 may be separated from each other. An embodiment in which the memory block BLKi is connected to eight gate lines GTL1, GTL2, ..., and GTL8 and three bit lines BL1, BL2, and BL3 is illustrated in FIG. 12, but an embodiment of the disclosure is not limited thereto.

The bit density of the memory block BLKi may vary according to the number of bits stored in each of the memory cells included in the memory block BLKi.

FIG. 13 is a diagram illustrating a configuration according to an embodiment of a memory device according to an embodiment of the disclosure. The memory device 120 to be described with reference to FIG. 13 may correspond to the memory device 120 of FIG. 1.

Referring to FIG. 13, the memory device 120 may include the memory cell array 121, a voltage generator 123, a row decoder 124, the control logic circuit 125, the page buffer circuit 126, a status register 128, and an input/output circuit 129.

The control logic circuit 125 may overall control various operations of the memory device 120. The control logic circuit 125 may output various control signals in response to the command CMD and/or the address ADDR from the memory interface circuit 118 (refer to FIG. 4). For example, the control signals may include a voltage control signal CTRL_vol, a row address X_ADDR, and a column address Y_ADDR.

The memory cell array 121 may include a plurality of memory blocks BLK1 to BLKz (where z is a positive integer). Each of the plurality of memory blocks BLK1 to BLKz may include a plurality of memory cells. The memory blocks BLK1 to BLKz may be connected to the page buffer circuit 126 through bit lines BL1 to BLn and may be connected to the row decoder 124 through word lines WL, string selection lines SSL, and ground selection lines GSL.

The page buffer circuit 126 may include a plurality of page buffers PB1 to PBn (where n is an integer of 3 or more). The plurality of page buffers PB1 to PBn may be respectively connected to memory cells included in each of the plurality of memory blocks BLK1 to BLKz through the plurality of bit lines BL1 to BLn. Each of the plurality of page buffers PB1 to PBn may include a latch. The page buffer circuit 126 may select at least one of the bit lines BL1 to BLn in response to the column address Y_ADDR. The page buffer circuit 126 may operate as a write driver or a sense amplifier according to an operation mode. For example, in the program operation, the page buffer circuit 126 may apply a bit line voltage corresponding to data DATA to be programmed to a selected bit line. In the read operation, the page buffer circuit 126 may sense a current or a voltage of the selected bit line to read data stored in a memory cell. The plurality of page buffers PB1 to PBn of the page buffer circuit 126 may sense data stored in memory cells through the plurality of bit lines BL1 to BLn and may temporarily store the sensed data as sensing data.

For example, the plurality of page buffers PB1 to PBn according to an embodiment of the disclosure may temporarily store data sensed from memory cells through the plurality of bit lines BL1 to BLn at a first time as the first sensing data.

The voltage generator 123 may generate various voltages for performing the program operation, read operation, the erase operation, etc. based on the voltage control signal CTRL_vol.

In response to the row address X_ADDR, the row decoder 124 may select one of the plurality of word lines WL and may select one of the plurality of string selection lines SSL.

In an embodiment, the page buffer circuit 126 according to an embodiment of the disclosure may send a plurality of sensing data SD sensed by using the plurality of sensing voltage signals to the control logic circuit 125

In an embodiment, the page buffer circuit 126 may send an on-cell count of each of the plurality of sensing data SD sensed by using the plurality of sensing voltage signals to the control logic circuit 125. For example, the page buffer circuit 126 may include an on-cell counting circuit.

The control logic circuit 125 may include the error detecting circuit 127. The error detecting circuit 127 may detect an error of data to be migrated, by using the plurality of sensing data SD or the on-cell count of each of the plurality of sensing data SD, as sent from the page buffer circuit 126. The control logic circuit 125 may compare a detected error with the preset criteria to determine whether there is a need to output the data to be migrated to the outside of the memory device 120.

The control logic circuit 125 may set the status register 128 based on an error comparison result obtained by comparing the error, which is detected from the data to be migrated, with the preset criteria. For example, when the detected error exceeds the preset criteria, the control logic circuit 125 may set some bit signals of the status register 128 to a bit value indicating “failure”.

In response to the status query command from the memory controller 110 of FIG. 1, the control logic circuit 125 may control the input/output circuit 129 to output the bit signal of the status register 128.

The control logic circuit 125 may program the data to be migrated, based on the error comparison result obtained by comparing the error, which is detected from the data to be migrated, with the preset criteria. For example, when the error comparison result of the first data stored in the first memory cells is in the preset criteria, the control logic circuit 125 may send a program signal to the page buffer circuit 126. The control logic circuit 125 may control the voltage generator 123 and the row decoder 124 such that a programming voltage may be applied to a word line corresponding to the second memory cells. In response to the program signal, the page buffer circuit 126 may set voltages of bit lines corresponding to the second memory cells based on the first data.

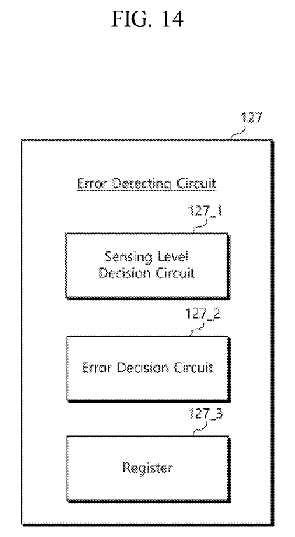

FIG. 14 is a block diagram illustrating an example of a configuration of the error detecting circuit 127 of FIG. 13.

Referring to FIG. 14, the error detecting circuit 127 may include a sensing level decision circuit 127_1, an error decision circuit 127_2, and a register 127_3.

The sensing level decision circuit 127_1 may decide levels of a plurality of voltage signals which are used to detect an error of data to be migrated. The plurality of voltage signals may be referred to as “sensing voltage signals”.

The sensing level decision circuit 127_1 may decide levels of sensing voltage signals based on information about a read voltage stored in the register 127_3.

In an embodiment, the sensing level decision circuit 127_1 may perform a develop operation of a word line until a level of a sensing voltage signal reaches a specific level, and the page buffer circuit 126 of FIG. 13 may sense data at a plurality of develop times belonging to the same develop process. For example, the plurality of develop times may correspond to the levels of the plurality of voltage signals. The change in the plurality of develop times may correspond to the change in the levels of the plurality of voltage signals.

In an embodiment, the sensing level decision circuit 127_1 may perform the develop operation multiple times until each of the plurality of sensing voltage signals reaches the sensing level. The page buffer circuit 126 of FIG. 13 may sense data in different develop processes.

The sensing level decision circuit 127_1 may perform sensing, which is based on the plurality of sensing voltage signals, multiple times. For example, the sensing level decision circuit 127_1 may perform a first sensing phase using the plurality of sensing voltage signals and may repeat additional sensing phases using the plurality of sensing voltage signals until an n-th sensing phase is completed (e.g., the sensing level decision circuit 127_1 may sequentially perform the first to n-th sensing phases).

In each sensing phase, the levels of the plurality of sensing voltage signals may be changed in various methods, and a method of changing the levels of the plurality of sensing voltage signals is not limited. For example, in an embodiment, the sensing level decision circuit 127_1 may decide the levels of the plurality of sensing voltage signals for each sensing phase, based on a preset offset table. In another example, the sensing level decision circuit 127_1 may compare on-cell counts of sensing data sensed based on the plurality of sensing voltage signals in the same sensing phase and may decide levels of the plurality of sensing voltage signals for a next phase (or subsequent phase) based on a comparison result of the on-cell counts.

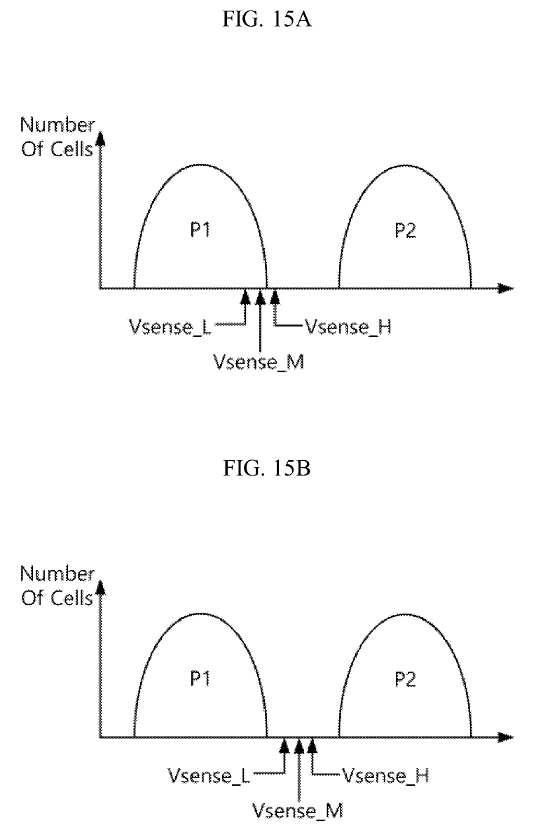

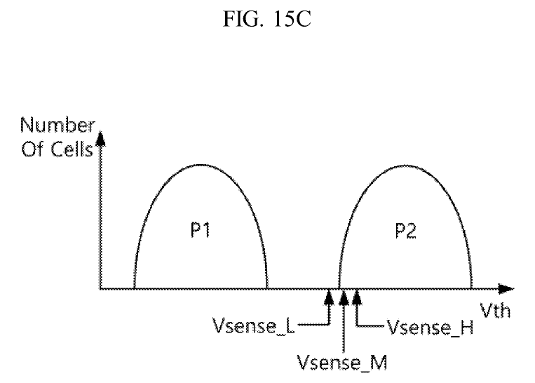

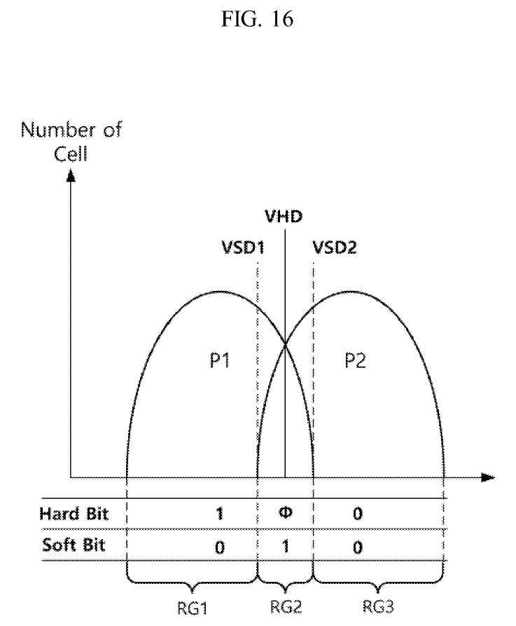

The error decision circuit 127_2 may decide an error of data to be migrated, based on the sensing data sensed by using the plurality of sensing voltage signals. For example, the error decision circuit 127_2 may decide an error of data by using a method according to the embodiment of FIGS. 15A, 15B, and 15C or FIG. 16 to be described below. The error decision circuit 127_2 may decide an error of data by using various methods in addition to the method according to the embodiment of FIGS. 15A, 15B, and 15C or FIG. 16, and a method of deciding an error of data is not limited. For example, the error decision circuit 127_2 may use an error decision method whose computational amount is low, in consideration of the area and performance of the control logic circuit 125.

The error decision circuit 127_2 may compare the decided error with the preset criteria and may output an error comparison result.

The register 127_3 may store information about criteria used for comparing an error level. The register 127_3 may store the offset table for changing voltage levels of the plurality of sensing voltage signals.

FIGS. 15A, 15B, and 15C are diagrams illustrating an embodiment of an error detecting method of an error detecting circuit. An error detecting method to be described with reference to FIGS. 15A, 15B, and 15C may be performed by the error detecting circuit 127 of FIG. 14.

For example, the embodiments of FIGS. 15A, 15B, and 15C describe that sensing is performed three times while changing voltage levels of a plurality of sensing voltage signals Vsense_L, Vsense_M, and Vsense_H. However, the number of sensing iterations is not limited.

In an embodiment, the error detecting circuit 127 may detect an error of data to be migrated by using the plurality of sensing voltage signals Vsense_L, Vsense_M, and Vsense_H.

Referring to FIG. 15A, the error detecting circuit 127 may calculate a first slope between on-cell counts of a plurality of sensing data respectively sensed by a first sensing voltage signal Vsense_L, a second sensing voltage signal Vsense_M, and a third sensing voltage signal Vsense_H. For example, the on-cell count of the sensing data sensed by using the first sensing voltage signal Vsense_L may be the greatest, and the on-cell count of the sensing data sensed by using the third sensing voltage signal Vsense_H may be the smallest.

In an embodiment, the error detecting circuit 127 may calculate a (1-1)-th slope between a first on-cell count of the sensing data sensed by using the first sensing voltage signal Vsense_L and a second on-cell count of the sensing data sensed by using the second sensing voltage signal Vsense_M and a (1-2)-th slope between the second on-cell count of the sensing data sensed by using the second sensing voltage signal Vsense_M and a third on-cell count of the sensing data sensed by using the third sensing voltage signal Vsense_H.

Likewise, in each of situations of FIGS. 15B and 15C, the error detecting circuit 127 may calculate a second slope and a third slope while changing the levels of the plurality of sensing voltage signals Vsense_L, Vsense_M, and Vsense_H. In an embodiment, as described above, the error detecting circuit 127 may calculate a (2-1)-th slope, a (2-2)-th slope, a (3-1)-th slope, and a (3-2)-th slope, respectively.

In an embodiment, the error detecting circuit 127 may decide a threshold voltage corresponding to a valley formed by the threshold voltage distributions P1 and P2, based on a change of each of the slopes. The error detecting circuit 127 may output an error comparison result based on the threshold voltage corresponding to the valley. For example, the error detecting circuit 127 may output the error comparison result by using an on-cell count of a plurality of sensing data sensed based on the threshold voltage corresponding to the valley.

In an embodiment, an on-cell count of a plurality of sensing data sensed based on a threshold voltage being a preset error criterion may be “0”. For example, corresponding to the case where the threshold voltage distributions of the first program state P1 and the second program state P2 may not overlap each other. When an on-cell count obtained by using the threshold voltage of the valley decided based on the plurality of sensing voltage signals Vsense_L, Vsense_M, and Vsense_H is “0”, the control logic circuit 125 may output the error comparison result satisfying the error criterion. For example, the control logic circuit 125 may internally perform migration without sending data to be migrated to the memory controller 110.

FIG. 16 is a diagram illustrating an embodiment of an error detecting method of an error detecting circuit. The error detecting method to be described with reference to FIG. 16 may be performed by the error detecting circuit 127 of FIG. 14.

In an embodiment, the error detecting circuit 127 may detect an error of data to be migrated by using soft decision data.

Referring to FIG. 16, a situation where the threshold voltage distribution of the first program state P1 and the threshold voltage distribution of the second program state P2 partially overlap each other is illustrated. When a threshold voltage of a memory cell is present in a first region RG1, the data of the memory cell may be sensed as hard-bit “1” by a hard decision voltage VHD applied thereto. When the threshold voltage of the memory cell is present in a third region RG3, the data of the memory cell may be sensed as hard-bit “0” by the hard decision voltage VHD applied thereto.

A soft-bit may be generated by performing an exclusive OR (XOR) operation on bit values sensed by using a first soft decision voltage VSD1 and a second soft decision voltage VSD2. Accordingly, when the threshold voltage of the memory cell is present in a second region RG2, the data of the memory cell may be sensed as a soft-bit “1”. When the memory cell is present in each of the remaining regions RG1 and RG3, the data of the memory cell may be sensed as soft-bit “0”.

In an embodiment, the error detecting circuit 127 may sense the soft-bit of the data to be migrated multiple times while changing the hard decision voltage VHD and the soft decision voltages VSD1 and VSD2. The error detecting circuit 127 may decide a sensing phase, in which the number of memory cells from which the soft-bit is sensed as “1” is the smallest, from among a plurality of sensing phases. The error detecting circuit 127 may decide the number of errors of the data to be migrated in consideration of the hard-bit and the soft-bit in a sensing phase where the number of memory cells from which the soft-bit is sensed as “1” is the smallest.

In an embodiment, when the preset error criterion for the number of memory cells from which the soft-bit being is sensed as “1” is “0”, and when a sensing phase, in which there are not detected memory cells from which the soft-bit is sensed as “1”, from among the plurality of sensing phases exists, the error detecting circuit 127 may output the error comparison result satisfying the error criterion.

According to embodiments of the disclosure, a storage device and an operating method thereof may improve the performance of the storage device.

According to embodiments of the disclosure, a storage device and an operating method thereof may improve the performance of the storage device by performing data migration in a memory device without exchanging data with the memory device.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A storage device comprising:
a memory device comprising a plurality of memory cells; and
a memory controller configured to control the memory device,
wherein the memory device comprises:
a memory cell array comprising the plurality of memory cells;
a control logic circuit configured to write data to the memory cell array or read data from the memory cell array in response to a command received from the memory controller; and
a page buffer configured to store sensing data sensed from the plurality of memory cells,
wherein the control logic circuit comprises an error detecting circuit configured to detect an error of first data stored in first memory cells of the memory cell array, and
wherein the control logic circuit is configured to write the first data to second memory cells of the memory cell array, based on an error comparison result obtained by comparing the error of the first data with a set value.

2. The storage device of claim 1, wherein, based on the error comparison result exceeding the set value, the control logic circuit is configured to set an error information bit of a status register to indicate failure.

3. The storage device of claim 1, wherein, based on the error comparison result not exceeding the set value, the control logic circuit is configured to send a signal that instructs programming of the sensing data to the second memory cells to the page buffer.

4. The storage device of claim 1, wherein the first memory cells are single level cells, and
wherein the second memory cells are multi-level cells, triple level cells, or quadruple level cells.

5. The storage device of claim 1, wherein the error detecting circuit is configured to detect the error of the first data in response to one of a read command and a migration command received from the memory controller.

6. The storage device of claim 5, wherein a reserved bit signal of the read command comprises a bit signal that instructs migration or error detection.

7. The storage device of claim 6, wherein the memory controller is configured to monitor a ready/busy signal, and
wherein the control logic circuit is configured to set the ready/busy signal to indicate a ready state and to change a status register based on the error comparison result.

8. The storage device of claim 5, wherein the control logic circuit is configured to change a status register based on the error comparison result, in response to receiving a status query command of the memory controller.

9. The storage device of claim 8, wherein the memory controller is configured to send a program command to the memory device in response to the change of the status register, and
wherein the control logic circuit is configured to program the first data to the second memory cells, based on the program command.

10. The storage device of claim 8, wherein the memory controller is configured to send a command that requests an output of the first data in response to the change of the status register, and
wherein an error correction code (ECC) module of the memory controller is configured to correct the error of the first data.

11. The storage device of claim 1, wherein the error detecting circuit is configured to:
sense the first memory cells by changing voltage levels of a plurality of sensing voltage signals; and
detect the error of the first data based on slopes of on-cell counts using the plurality of sensing voltage signals.

12. The storage device of claim 11, wherein the error detecting circuit is configured to:
decide a first plurality of sensing voltage signals having a smallest slope among the slopes of the on-cell counts; and
compare an on-cell count, which is obtained using a sensing voltage signal corresponding to a middle level from among the first plurality of sensing voltage signals, with the set value.

13. The storage device of claim 11, wherein the error detecting circuit is configured to compare a smallest slope among the slopes of the on-cell counts with the set value.

14. The storage device of claim 1, wherein the error detecting circuit is configured to:
perform soft decision of the first memory cells using soft decision voltages; and
detect the error of the first data based on soft decision data of the first memory cells.

15. A storage device comprising:
a memory device comprising a plurality of memory cells; and
a memory controller configured to control the memory device,
wherein the memory device comprises:
a memory cell array comprising the plurality of memory cells;
a control logic circuit configured to write data to the memory cell array or read data from the memory cell array in response to a command received from the memory controller; and
a page buffer configured to store sensing data sensed from the plurality of memory cells,
wherein the control logic circuit comprises an error detecting circuit configured to compare a change in an on-cell count of first memory cells among the plurality of memory cells with a set value to generate a comparison result by changing voltage levels of a plurality of sensing voltages, and
wherein the control logic circuit is configured to write first data of the first memory cells to second memory cells among the plurality of memory cells, based on the comparison result.

16. The storage device of claim 15, wherein the control logic circuit is configured to set an error information bit of a status register to indicate failure or success, based on the comparison result.

17. The storage device of claim 16, wherein the memory controller is configured to send a command that instructs an output of the first data to the memory device, based on the status register.

18. The storage device of claim 17, wherein, after the memory controller performs error correction on the first data, the memory controller is configured to send a command for writing the first data to the second memory cells to the memory device.

19. The storage device of claim 15, wherein the error detecting circuit is configured to compare the change in the on-cell count of the first memory cells with the set value in response to one of a read command and a migration command received from the memory controller, and
wherein a reserved bit signal of the read command comprises a bit signal instructing migration or error detection.

20. An operating method of a storage device, comprising:
sending, by a memory controller configured to control a memory device, a first command to the memory device;
detecting an error of first data stored in first memory cells of a memory cell array in response to the first command;
comparing the error of the first data with a set value to generate an error comparison result; and
writing the first data to second memory cells of the memory cell array based on the error comparison result.
